(19) United States
(12) Patent Application Publication
(10) Pub. No.: US 2025/0029860 A1
(43) Pub. Date: Jan. 23, 2025

(54) NESTING ATMOSPHERIC ROBOT ARMS FOR HIGH THROUGHPUT

(71) Applicant: Lam Research Corporation, Fremont, CA (US)

(72) Inventor: Richard M. Blank, San Jose, CA (US)

(21) Appl. No.: 18/708,586

(22) PCT Filed: Nov. 9, 2022
(86) PCT No.: PCT/US2022/079585

§ 371 Date: May 8, 2024

Related U.S. Application Data
(60) Provisional application No. 63/263,937, filed on Nov. 11, 2021.

(51) Int. Cl. H01L 21/677; B25J 9/00; B25J 9/04; B25J 9/16

(52) U.S. Cl. CPC H01L 21/67766; B25J 9/0087; B25J 9/042; B25J 9/1682; H01L 21/67781

(57) ABSTRACT

Nesting wafer handling robot arms are provided that may be used to move semiconductor wafers between various wafer placement locations in a semiconductor processing tool. The nesting wafer handling robot arms may be configured so that each wafer handling may be able to translate along a translation system and pick and place wafers independent of what the other wafer handling may be doing. The two wafer handling robot arms may enter a nesting configuration so that each wafer handling robot may concurrently pick or place wafers from wafer placement locations where one wafer placement location is directly above the other.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor wafer processing tools may have an equipment front-end module (EFEM) to pass wafers from storage containers, e.g., front-opening universal (or unified) pods (FOUPs), to processing chambers. The EFEM may have one or more wafer storage containers and one or more processing chamber load ports, e.g., load lock. The load lock is a chamber that changes pressure to match the pressure where the wafer is being transferred to or from. In some embodiments, the load lock may have single placement location to hold wafers. In some other embodiments, the load lock may have a plurality of wafer placement locations to hold a plurality of wafers. During wafer processing, a load lock may wait for wafers to be placed into each of the wafer placement locations before pressurizing the load lock chamber. The EFEM, in most cases, may include a wafer handling robot to transfer wafers between the storage containers, load lock, and/or other locations.

### SUMMARY

In some implementations, an apparatus for transferring wafers in a semiconductor processing tool may be provided. The apparatus may include a first wafer handling robot arm, a second wafer handling robot arm, and a linear translation system configured to interface with the first and the second wafer handling robot arms. The first wafer handling robot arm and the second wafer handling robot arm may each have a corresponding base. The apparatus may be configured to cause the bases to independently traverse along a horizontal translation axis between at least a nested configuration and a non-nested configuration. The linear translation system, the first wafer handling robot arm, and the second wafer handling robot arm may be configured such that the base of the first wafer handling robot arm is movable by the linear translation system, along the translation axis, and through a first zone and a second zone but not a third zone, and such that the base of the second wafer handling robot arm is movable by the linear translation system, through the second zone and the third zone but not the first zone. The second zone is between the first zone and the third zone.

In some implementations of the apparatus, the first wafer handling robot arm and the second wafer handling robot arm may each further include a corresponding end effector and two or more corresponding robot arm links including at least (a) a corresponding first robot arm link with a corresponding first end and a corresponding second end, with the first end of the corresponding first robot arm link rotatably connected to the corresponding base via a corresponding first rotational joint such that the corresponding first robot arm link is rotatable relative to the corresponding base about a corresponding first axis, and (b) a corresponding second robot arm link with a first end and a second end, with the second end of the corresponding second robot arm link rotatably connected with the corresponding end effector via a corresponding second rotational joint such that the corresponding end effector is rotatable relative to the corresponding second robot arm link about a corresponding second axis.

In some implementations of the apparatus, the corresponding bases of the first wafer handling robot arm and the second wafer handling robot arm may each have a corresponding vertical drive mechanism configured to cause the corresponding end effector to move along an axis parallel to the corresponding first axis.

In some implementations of the apparatus, the linear translation system may include a first set of linear guides and both the first wafer handling robot arm and the second wafer handling robot arm may be movably connected with the first set of linear guides.

In some implementations of the apparatus, the linear translation system may have a first set of linear guides and a second set of linear guides, the first wafer handling robot arm may be movably connected with the first set of linear guides, and the second wafer handling robot arm may be movably connected with the second set of linear guides.

In some implementations of the apparatus, a bottom surface of the end effector of the first wafer handling robot arm may face towards a top surface of the second robot arm link of the first wafer handling robot arm.

In some implementations of the apparatus, a top surface of the end effector of the second wafer handling robot arm may face towards a bottom surface of the second robot arm link of the second wafer handling robot arm.

In some implementations of the apparatus, a substrate support surface of the end effector of the first wafer handling robot arm may be a first distance above a top surface of the first robot arm link of the first wafer handling robot arm and a substrate support surface of the end effector of the second wafer handling robot arm may be a second distance above a top surface of the first robot arm link of the second wafer handling robot arm. The difference between the first distance and the second distance may be 10 mm±1 mm.

In some implementations of the apparatus, each wafer handling robot arm may have a corresponding second end effector.

In some implementations of the apparatus, the apparatus may further include a controller having one or more memory devices communicatively connected with one or more processors.

In some implementations of the apparatus, the controller may be configured to cause the first and second wafer handling robot arms to move between at least a first configuration and a second configuration. In the first configuration, the first and second wafer handling robot arms may be positioned such that the end effector of the second wafer handling robot arm is directly above the end effector of the first wafer handling robot arm and the first axis of the second wafer handling robot arm is spaced a first distance apart from the first axis of the first wafer handling robot arm. In the second configuration, the first and second wafer handling robot arms may be positioned such that the end effector of the second wafer handling robot arm is a horizontal distance apart from the end effector of the first wafer handling robot arm and the first axis of the second wafer handling robot arm is spaced a second distance apart from the first axis of the first wafer handling robot arm, and the second distance may be greater than the first distance.

In some implementations of the apparatus, in the first configuration, a substrate support surface of the end effector of the first wafer handling robot arm may be 10 mm±1 mm below a substrate support surface of the end effector of the second wafer handling robot arm.

In some implementations of the apparatus, the controller may be configured to cause the linear translation system to move the corresponding base of one of the wafer handling robot arms along the translation axis while the corresponding base of the other wafer handling robot arm remains stationary relative to the linear translation system.

In some implementations of the apparatus, the controller may be configured to cause the linear translation system to move the corresponding base of the first wafer handling arm robot along the translation axis and in a first direction and to cause the linear translation system to move the corresponding base of the second wafer handling robot arm along the translation axis in a second direction.

In some implementations of the apparatus, the first direction and second direction may be the same direction.

In some implementations of the apparatus, the first axis of the first wafer handling robot arm and the first axis of the second wafer handling robot arm may remain a first spacing distance apart while the first and second wafer handling robot arms translate along linear translation axis.

In some implementations of the apparatus, the first direction and second directions may be different directions.

In some implementations of the apparatus, the controller may be configured to cause the first wafer handling robot arm to pick a first substrate from a first wafer placement location and to cause the second wafer handling robot arm to concurrently pick a second substrate from a second wafer placement location, the first wafer placement location positioned above or below the second wafer placement location.

In some implementations of the apparatus, the controller may be configured to cause the first wafer handling robot arm to pick a first substrate from a first wafer placement location and to cause the second wafer handling robot arm to concurrently pick a second substrate from a second wafer placement location, the second wafer placement location spaced a horizontal distance apart from the first wafer placement location.

In some implementations of the apparatus, the controller may be further configured to cause the first wafer handling robot arm to place the first substrate at a third wafer placement location and to cause the second wafer handling robot arm to concurrently place the second substrate at a fourth wafer placement location, the third wafer placement location positioned above or below the fourth wafer placement location.

In some implementations of the apparatus, the controller may be further configured to cause the first wafer handling robot arm to place the first substrate at a third wafer placement location and to cause the second wafer handling robot arm to concurrently place the second substrate at a fourth wafer placement location, the third wafer placement location spaced a horizontal distance apart from the fourth placement wafer location.

In some implementations of the apparatus, the apparatus may further include three or more load ports and two or more load locks. The three or more load ports may be located on a first side of the linear translation system, the two or more load locks on a second side of the linear translation system opposite the first side, and each of the three or more load ports may be configured to receive a corresponding front opening universal pod.

In some implementations of the apparatus, the apparatus may further include two or more aligners, with each aligner located above a corresponding load lock.

In some implementations of the apparatus, the controller may be further configured to cause the first wafer handling robot arm to pick a first substrate from a first front opening universal pod and to cause the second wafer handling robot arm to concurrently pick a second substrate from the first front opening universal pod.

In some implementations of the apparatus, the controller may be further configured to cause the first wafer handling robot arm to pick a first substrate from a first front opening universal pod and to cause the second wafer handling robot arm to concurrently pick a second substrate from a second front opening universal pod.

In some implementations of the apparatus, the controller may be further configured to cause the first wafer handling robot arm to place the first substrate into a first load lock and to cause the second wafer handling robot arm to concurrently place the second substrate into a second load lock.

In some implementations of the apparatus, the controller may be further configured to cause the first wafer handling robot arm to place the first substrate onto a first aligner and to cause the second wafer handling robot arm to concurrently place the second substrate onto a second aligner.

In some implementations of the apparatus, the controller may be further configured to cause the first wafer handling robot arm to place a first substrate into a load lock and to cause the second wafer handling robot arm to concurrently place a second substrate on an aligner.

In some implementations of the apparatus, the linear translation system may be a linkage-based translation system that has a first set of linkages connected with, and supporting, the base of the first wafer handling robot arm and a second set of linkages connected with, and supporting, the base of the second wafer handling robot arm.

In some implementations of the apparatus, the linkage-based translation system may have a base and each set of linkages may have at least (a) a corresponding first link with a corresponding first end and a corresponding second end, with the first end thereof rotatably connected to the base of the linkage-based translation system via a corresponding first rotational joint such that the corresponding first link is rotatable relative to the base of the linkage-based translation system about a corresponding a first axis, and (b) a corresponding second link with a first end and a second end, with the first end thereof rotatably connected with the second end of the corresponding first link and the second end thereof rotatably connected with the base of a corresponding one of the wafer handling robot arms via a corresponding rotational joint such that the corresponding wafer handling robot arm is rotatable relative to the corresponding second link about a corresponding second axis.

In some implementations of the apparatus, the linkage-based translation system may be configured such that the second end of each second link is constrained to move along the translation axis.

In some implementations of the apparatus, the linkage-based translation system may be configured such that the second end of each second link is constrained to move along a translation plane that is perpendicular to the first axes.

### BRIEF DESCRIPTION OF DRAWINGS

FIG. 1 depicts a top view of an example equipment front-end module.

FIG. 2 depicts a perspective view of example nesting wafer handling robot arms mounted to a translation system.

FIG. 3 depicts a top view of example wafer handling robot arms.

FIG. 4 depicts a perspective view of example nesting wafer handling robot arms in a nested configuration mounted to a translation system.

FIG. 5 depicts a cross-sectional view of an example of a wafer handling robot arm.

FIG. 6 shows an example of a translation system with a single set of linear guides.

FIG. 7 shows an example of a translation system with two sets of linear guides.

FIGS. 8-A through 8-D depict schematics of nesting wafer handling robot arms on a translation system after various translations.

FIG. 9 depicts a side view of example nesting wafer handling robot arms in a nested configuration picking wafers.

FIG. 10 depicts a perspective view of example nesting wafer handling robot arms mounted to a translation system.

FIG. 11 depicts yet another perspective view of example nesting wafer handling robot arms mounted to a translation system.

FIG. 12 depicts a perspective view of another example of nesting wafer handling robot arms mounted to a translation system.

FIG. 13 depicts the example of nesting wafer handling robot arms of FIG. 12 in a different configuration.

FIG. 14 shows a schematic of an example equipment front-end module with nesting wafer handling robot arms.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

As semiconductor wafer processing tools continue to improve, throughput—the number of wafers that such tools can potentially process in a given period of time—continues to be benchmark upon which tools are graded. A significant factor affecting tool throughput is the time spent transferring wafers between various locations within the tool, in particular, wafer transfers occurring in the Equipment Front End Module (EFEM) can cause a significant delay. Provided herein are apparatuses having nesting wafer handling robot arms which may be used to increase efficiency in wafer transfer and tool throughput. In certain embodiments, the apparatuses may be used to transfer multiple wafers concurrently from a first location for each corresponding wafer to a second location for each corresponding wafer. By using nesting wafer handling robot arms, the semiconductor wafer processing tool decreases wait times for wafer transfer and allows the tool to significantly improve semiconductor processing time.

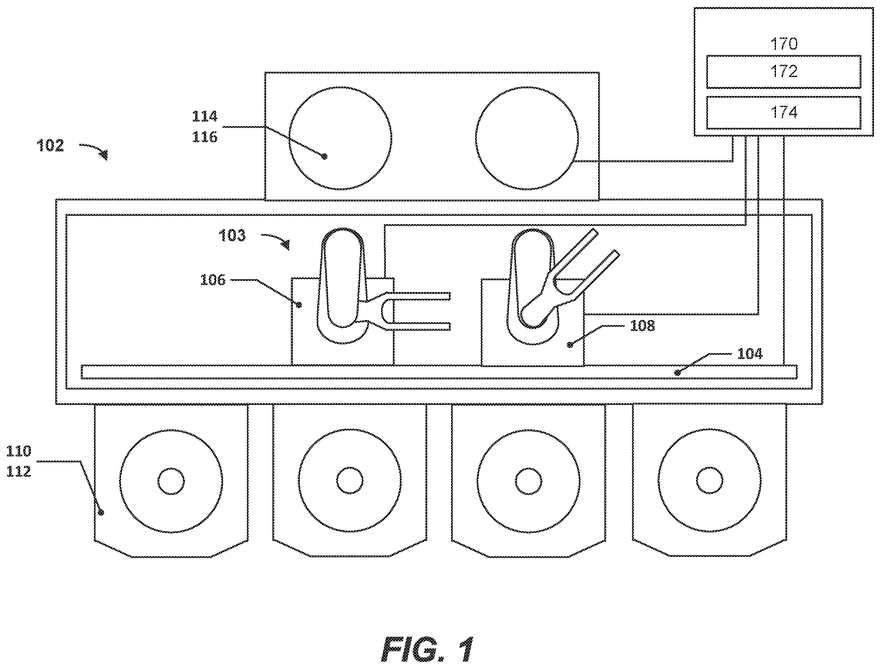

FIG. 1 shows an example of an EFEM 102 of a semiconductor wafer processing tool. In the EFEM 102 are nesting wafer handling robot arms 103. The nesting wafer handling robot arms 103 connect to a linear translation system 104. The nesting wafer handling robot arms 103 are two wafer handling robot arms, a first wafer handling robot arm 106 and a second wafer handling robot arm 108. On the outside of the EFEM 102 are load ports 110 which may hold wafer storage units, i.e., front-opening universal pods (FOUPs) 112. In the embodiment shown in FIG. 1, there are four load ports 110, each with a corresponding FOUP 112. In other embodiments, there may be multiple load ports. Opposite the load ports 110, the EFEM 102 may have multiple load locks 114. In the embodiment shown, there are two load locks 114 each with a corresponding aligner 116 on top. In some embodiments, the EFEM 102 may have a single load lock 114. FIG. 1 also features a controller 170 with one or more processors 172 and a memory 174, which will be discussed further below.

The EFEM 102, generally speaking, is the front-end of the semiconductor processing tool and is an environment with atmospheric or near-atmospheric pressure. The load ports 110, the FOUPs 112, and the nesting wafer handling robot arms 103 are in the atmospheric environment, The load locks 114 transfer semiconductor wafers between the EFEM 102 and process chambers, which generally have a pressure below atmospheric pressure. The load locks 114 may be either bidirectional (holding inbound and outbound wafers) or unidirectional (holding only inbound or outbound wafers). During a wafer transfer between the atmospheric environment and the processing chamber, the load lock is able to change the pressure within the load lock. For example, when a to-be-processed semiconductor wafer is transferred from a FOUP to the processing chamber, one wafer handling robot arm of the nesting wafer handling robot arms 103 will transfer the semiconductor wafer to the load lock 114. Once the semiconductor wafer is in the load lock 114, the load lock will change the internal pressure from atmospheric pressure to the pressure of a connected chamber. In some embodiments the connected chamber is a transfer chamber. In some embodiments the connected chamber is the process chamber. When the internal pressure of the load lock matches the pressure of the connected chamber, the semiconductor wafer is transferred from the load lock 114 to the connected chamber. In the embodiments where the connected chamber is a transfer chamber, the semiconductor wafer may be transferred to the process chamber via the transfer chamber. A similar process occurs when the semiconductor wafer is transferred from the process chamber to the atmospheric environment. The load lock 114 becomes the bottle neck for wafer throughput because the semiconductor wafer has to remain in the load lock while the load lock changes pressure. In some embodiments, as shown in FIG. 1, there may be multiple wafers that are able to be transferred through the load lock 114 at one time. This may be used to increase wafer throughput as multiple wafers may be transferred concurrently through the load lock 114 from either the atmospheric environment to the process chamber or from the process chamber to the atmospheric environment. In these embodiments, serial wafer placement into and serial wafer pick from the load lock 114 slows throughput, as the chamber must wait additional time for the wafers to be loaded prior to changing the internal pressure of the load lock. Nesting wafer handling robot arms 103 may be used so that wafer pick and placement actions from locations in the EFEM 102 such as the load lock 114 may be done in parallel, potentially leading to improved wafer throughput.

In some embodiments, the nesting wafer handling robots 103 and linear translation system 104 may be used in a vacuum transfer module (not shown). The vacuum transfer module may be connected with two or more wafer processing modules. In some embodiments, the vacuum transfer module may also be connected with one or more load locks configured to transfer wafers from the vacuum transfer module to the EFEM. The nesting wafer handling robots 103 and linear translation system may be used to increase wafer throughput as multiple wafers may be transferred concurrently between wafer processing modules and/or load locks by the nesting wafer handling robots.

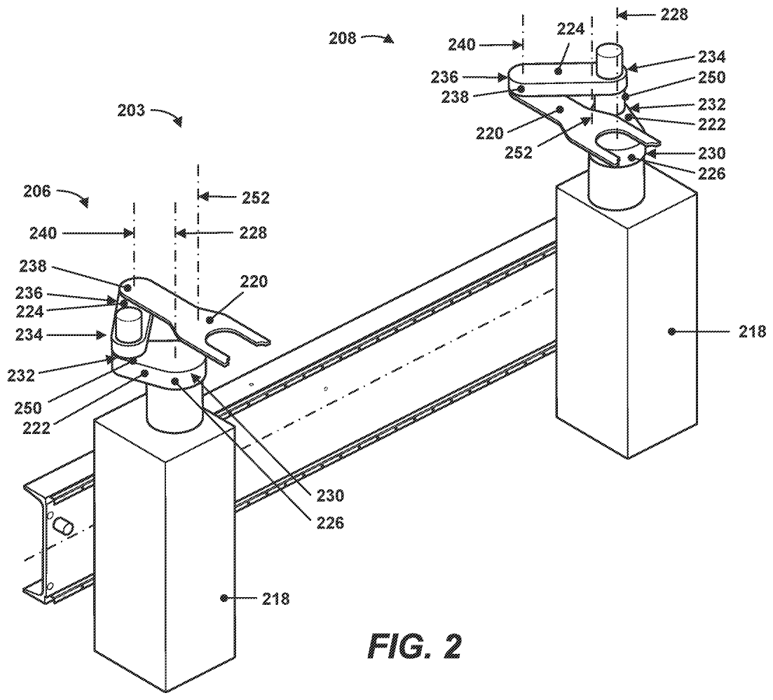

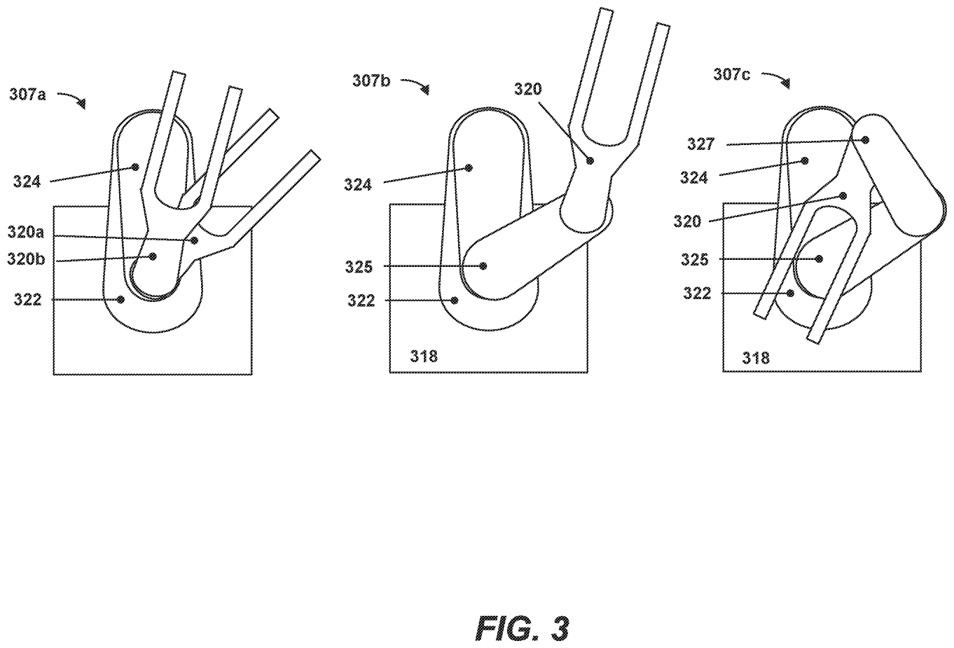

FIG. 2 shows an isometric view of nesting wafer handling robot arms 203 according to some embodiments of the present disclosure. The nesting wafer handling robot arms 203 may be used as the nesting wafer handling robot arms 103 shown in FIG. 1. The nesting wafer handling robot arms 203 include two wafer handling robot arms, a first wafer handling robot arm 206 and a second wafer handling robot arm 208. Each wafer handling robot arm has a base 218, robot arm links, and an end effector 220. In the embodiment shown in FIG. 2, each wafer handling robot arm (206 and 208) has a corresponding base 218, a corresponding first arm link 222, a corresponding second arm link 224, and an end effector 220. In some embodiments, one or more of the wafer handling robot arms may have dual end effectors (not shown). FIG. 3 shows examples of wafer handling robot arms 307a-307c (collectively, 307) that may be used in the nesting wafer handling robot arms 203, although other examples not depicted may also be used. The first example of a wafer handling robot arm 307a has dual end effectors 320a and 320b. The wafer handling robot arm 307a has two arm links, a first arm link 322 and a second arm link 324. The dual end effectors 320a and 320b are attached to the second arm link 324, although in some implementations, only a single end effector may be attached to the second arm link 324. In some embodiments, the dual end effectors may be used to carry multiple wafers concurrently. In some other embodiments, a first end effector 320a may be used to carry to-be-processed wafers while a second end effector 320b may be used to carry processed wafers.

The second example of a wafer handling robot arm 307b shows a wafer handling robot arm with a single end effector 320 and three arm links. A first arm link 322 is rotatably connected to a base 318. A second arm link 324 is rotatably connected to the first arm link 322. A third arm link 325 is rotatably connected to the second arm link 324. The end effector 320 is rotatably connected to the third arm link 325. The third arm link 325 may be used to extend the reach of the wafer handling robot arm and give the robot arm more degrees of freedom when compared to wafer handling robot arm with two arm links as shown in FIG. 2.

Similarly, the third example of a wafer handling robot arm 307c shows a wafer handling robot arm with a single end effector 320 and four arm links. A first arm link 322 is rotatably connected to a base 318. A second arm link 324 is rotatably connected to the first arm link 322. A third arm link 325 is rotatably connected to the second arm link 324. The fourth arm link 327 is rotatably connected to the third arm link 325 and the end effector 320 is rotatably connected to the fourth arm link 327. Similar to the wafer handling robot arm with three links, the wafer handling robot arm with four links allows for an extended reach and more degrees of freedom, giving the robot arm more possible configurations. The above examples are provided to illustrate examples of some wafer handling robot arms that may be used as nesting wafer handling robot arms. These examples are provided to exemplify and more clearly illustrate aspects of the present disclosure and are not intended to be limiting; other implementations may, for example, include additional end effectors and/or arm links. In some instances, a single base may support multiple robot arms, each with its own end effector(s).

Moving back to FIG. 2, the wafer handling robot arms shown each have two arm links and a single end effector 220. The first arm link 222 has two ends, a first arm link first end 230 and a first arm link second end 232. The first arm link first end 230 of the first arm link 222 is rotatably connected to the base 218 via a first rotational joint 226 and rotates about a first axis 228. The second arm link 224 has a second arm link first end 234 and a second arm link second end 236. The second arm link 224 at the second arm link first end 234 is rotatably connected to the first arm link 222 at the first arm link second end 232 via a rotational elbow joint 250. The end effector 220 is rotatably connected to the second arm link 224 at the second arm link second end 236 via a second rotational joint 238 and rotates about a second axis 240.

The rotation of each of the rotational joints are driven by actuators (not shown). In some embodiments, each rotational joint has its own actuator. In other embodiments, two or more rotational joints may share a single actuator. In these embodiments, the two rotational joints may be rotatably connected to each other. For example, when the second rotational joint 238 and the elbow rotational joint 250 are rotatably connected to each other, the two rotational joints may be connected via a pulley and belt system (not shown) which causes the second rotational joint 238 to rotate when the elbow rotational joint 250 is rotated. By having rotation at the first rotational joint 226, the rotational elbow joint 250, and the second rotational joint 238, each of the wafer handling robot arms is able to move their corresponding end effector 220 relative to their corresponding first axis 228 located in the first rotational joint 226. The rotatable connection between the first arm link 222 and the base 218 at the first rotational joint 226 allows the corresponding end effector 220 to be rotatable about the first axis 228. The rotatable connections between the first arm link 222 and the second arm link 224 at the rotational elbow joint 250 and between the second arm link and the end effector 220 at the second rotational joint 238 allow the end effector to extend outward and retract inward relative to the first axis 228. In some embodiments, the rotational elbow joint 250 may be rotatably connected to the second rotational joint 238 so that rotation of the elbow joint causes the second rotational joint to rotate in a manner which causes the end effector 220 to extend and retract in a radial direction relative to the first axis 228.

Each of the wafer handling robot arms (206 and 208) may have a vertical drive mechanism (not shown) which may be configured to move the corresponding end effector 220 along a z-drive axis 252. The z-drive axis 252 is parallel to the first axis 228. The vertical drive mechanism may be mounted in the base 218 and may move the end effector 220 along with the first arm link 222 and the second arm link 224 along the z-drive axis 252. The vertical drive mechanism, for example, may be a linear drive assembly using a lead screw driven by a rotational motor.

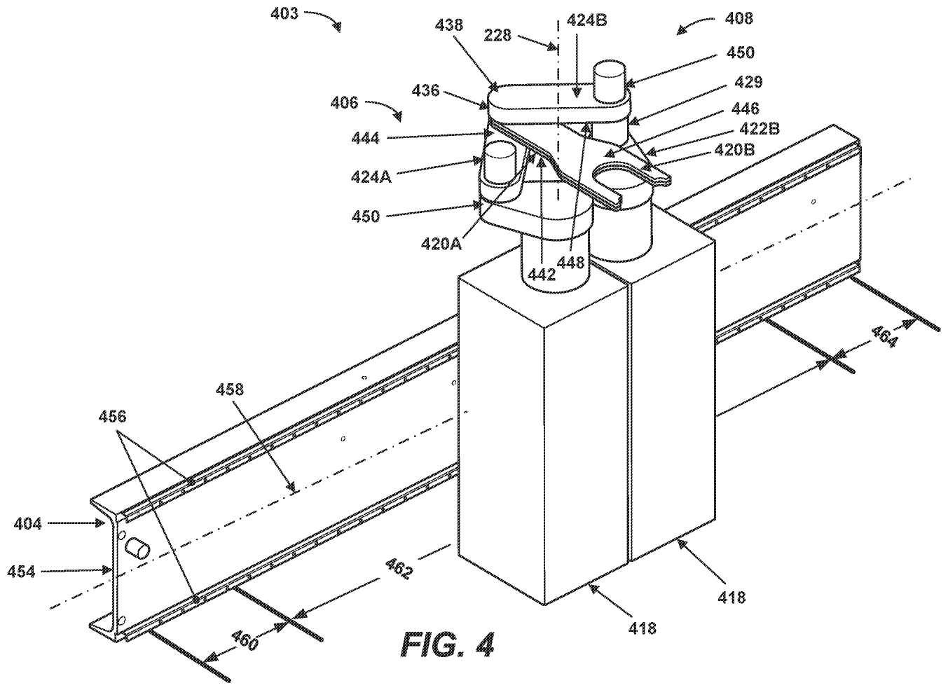

FIG. 4 shows nesting wafer handling robot arms 403 in a “perfect nest” configuration, in which an end effector 420A of a first wafer handling robot arm 406 is vertically in line with an end effector 420B of a second wafer handling robot arm 408. A perfect nested configuration is a specific type of a “nested” configuration. A nested configuration is where at least a portion of the end effector 420A of the first wafer handling robot arm 406 is above or below the end effector 420b of the second wafer handling robot. The nested configuration allows the nesting wafer handling robot arms 403 to concurrently pick and place wafers which are located above one another. A perfect nested configuration is one in which the end effectors are positioned such that the centers of wafers supported thereby are directly over/under one another; it is to be understood that references to “nested” configurations herein are inclusive of both perfect nested configurations and other nested configurations. A “non-nested” configuration is where no portion of the end effector 420 of the first wafer handling robot is above or below the end effector 420b of the second wafer handling robot.

FIG. 4 shows nesting wafer handling robot arms 403 in a nested configuration, specifically a perfect nested configuration. In the nested configuration, the nesting wafer handling robot arms 403 are configured so that each wafer handling robot arm, for example, may pick or place wafers at a single FOUP concurrently. The nesting wafer handling robot arms 403 may be configured to concurrently pick from any two locations within a FOUP where wafers may be held and have their corresponding end effectors spaced accordingly. Generally speaking, the wafer spacing in a FOUP is usually 10 mm from center to center (although it will be understood that the discussion below may be equally applicable to FOUP wafer spacings other than 10 mm spacing, with appropriate substitutions). In this example, when the nesting wafer handling robot arms 403 are in the nested configuration to pick from a FOUP, the end effectors 420 should be vertically spaced a multiple of 10 mm apart, e.g., 10 mm, 20 mm, 30 mm, etc. To achieve the nested configuration where the vertical spacing is a minimal distance, e.g., 10 mm, the corresponding end effectors 420 may be mounted differently for each of the wafer handling robot arms (406 and 408). As shown, the first wafer handling robot arm 406 has the end effector 420A mounted so that a bottom surface 442 of the corresponding end effector faces toward a second arm link top surface 444 of a corresponding second arm link 424A. The second wafer handling robot arm 408 has the end effector 420B mounted so that a top surface 446 of the corresponding end effector faces towards a second arm link bottom surface 448 of a corresponding second arm link 424B. To account for the variable mounting configurations of the end effector, the second arm link 424 (424a and 424b) of each of the wafer handling robot arms may be mounted at a different height at the elbow rotational joint 450. In some embodiments, the difference in height may be created by using a spacer 429 in one of the two wafer handling robot arms. For example, the second wafer handling robot arm 408 has the spacer 429 between the first arm link 422B and the second arm link 424B and the first wafer handling robot arm 406 does not have a spacer. In some embodiments, both wafer handling robot arms may have a spacer, but the spacer in the second wafer handling robot arm 408 may be taller than the spacer in the first wafer handling robot arm 406. The various end effector 420 mounting configurations enable the nesting wafer handling robot arms to move into a nested configuration and pick or place wafers with minimal spacing in the z-direction.

In FIG. 4, the depicted embodiment has both the first wafer handling robot arm 406 and the second wafer handling robot arm 408, each with a single corresponding end effector 420 (420a or 420b). Each end effector 420 is mounted to the corresponding second rotational joint 438. In some embodiments, each of the wafer handling robot arms may have a wrist mount (not shown) that adds an additional degree of freedom in a wrist axis. In this embodiment, the wrist mount mounts between the second arm link second end 436 and the end effector 420 where the second rotational joint 438 is located. In some embodiments, each of the wafer handling robot arms may have two or more end effectors as discussed above in FIG. 3. In some of these embodiments, the end effectors may be each rotatably connected to the same rotational joint. In some other embodiments, the end effectors may be connected to two different rotational joints and are independently rotatable from one another.

The first wafer handling robot arm 406 and the second wafer handling robot arm 408 are each connected to the linear translation system 404. The linear translation system 404 has a frame 454 and a set of linear guides 456 attached to the frame. In some embodiments, the linear translation system 404 may have only one set of linear guides 456 for both the first wafer handling robot arm 406 and the second wafer handling robot arm 408. In some other embodiments, the linear translation system 404 may have two sets (not shown) of linear guides 456, one set of linear guides for the first wafer handling robot arm 406 and a second set of linear guides for the second wafer handling robot arm 408. The linear guides 456 may be, for example, rails, tracks, slides, etc. Shown in FIG. 4 is a linear translation system 404 with a single set of linear guides 456. Each of the wafer handling robot arms is mounted to the set of linear guides 456 so that each wafer handling robot arm is able to move independently along a translation axis 458. The translation axis 458 is substantially parallel to the set of linear guides 456 and is perpendicular to the first axis 428.

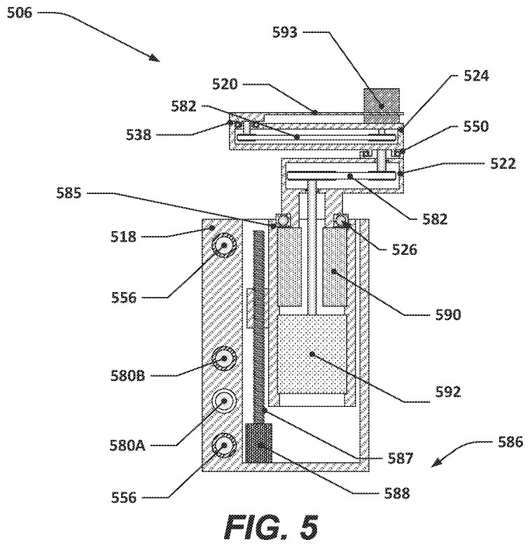

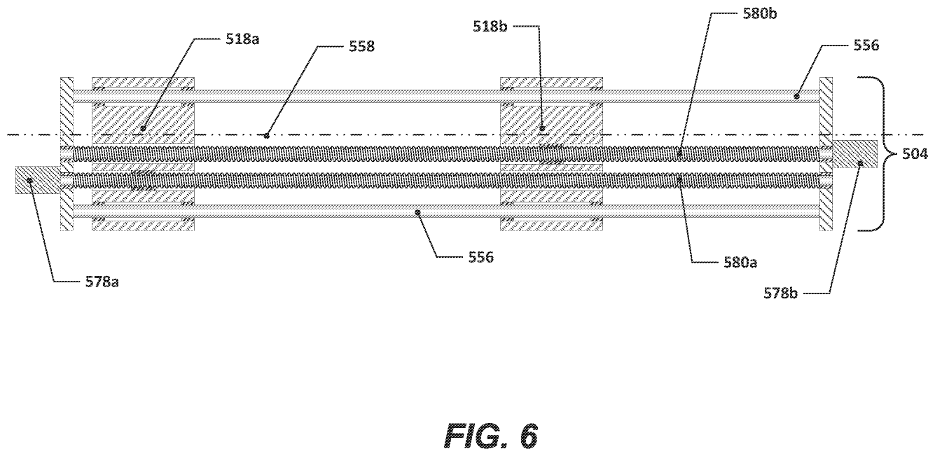

FIG. 5 shows a cross-sectional view of an example of a wafer handling robot arm 506 that may be used in the nesting wafer handling robot arms 103. Shown in FIG. 5, the wafer handling robot arm 506 has a base 518 configured to translate along a set of linear guides 556. In another embodiment, the base 518 may mount to a plate (not shown) or bracket (not shown) which may be configured to slide along the set of linear guides. The base 518 may be driven by a linear drive screw 580 (e.g., 580a, 580b). In the embodiment shown, there is a first linear drive screw 580a and a second linear drive screw 580b. The first linear drive screw 580a may be configured to drive the wafer handling robot arm 506 and the second linear drive screw 580b may be configured to drive a second wafer handling robot arm (not shown). This will be discussed further below with respect to FIG. 6. The wafer handling robot arm 506 may have an end effector 520, a first arm link 522, and a second arm link 524. The first arm link 522 is rotatably connected to the base 518 by the first rotational joint 526. The second arm link 524 is rotatably connected to the first arm link 522 by the elbow rotation joint 550. The end effector 520 is rotatably connected to the second arm link 524 by a second rotational joint 538. Motors 590 and 592 and pulleys 582 may be used to move each of the arm links. The set of arm links and end effector 520 may be moved along a z-direction by a vertical drive mechanism 586. In the example shown, the vertical drive mechanism 586 includes a z-axis drive motor 588 and a z-drive lead screw 587. A first motor 590 may be configured to control the rotation of the first arm link 522 around the first rotational joint 526. A second motor 592 combined with the configuration of the pulleys 582 may be used to extend and retract the arm links. In some embodiments, the second motor 592 and pulleys 582 may be configured to control the end effector 520. In the embodiment shown, the wafer handling robot arm 506 has an end effector drive motor 593 configured to drive the end effector 520 around the second rotational joint 538.

FIG. 6 shows an example of a linear translation system 504. In the example shown, there is a single set of linear guides 556 with a first base 518a for the first wafer handling robot arm (not shown) and a second base 518b for the second wafer handling robot arm (not shown). In some embodiments, the base 518 may mount to a plate or bracket configured to translate along the linear guides 556. The linear guides 556 are substantially parallel to a translation axis 558. Each base 518 may be driven along the translation axis 558 by a linear drive system. In this example, the linear drive system includes a linear drive motor 578 and linear drive screw 580 (580a and 580b). Each base 518 may be driven by a corresponding linear drive system. For example, the first base 518a for the first wafer handling robot arm may be driven by a first drive motor 578 and a first linear drive screw 580a and the base 518b for the second wafer handling robot arm may be driven by a second drive motor 578b and a second linear drive screw 580b. In some embodiments, a control system (not shown), discussed further below, may be able to control each linear drive motor 578a and 578b to cause the base 518 of each wafer handling robot arm to translate along the translation axis 558 independent of the base of the other wafer handling robot arm.

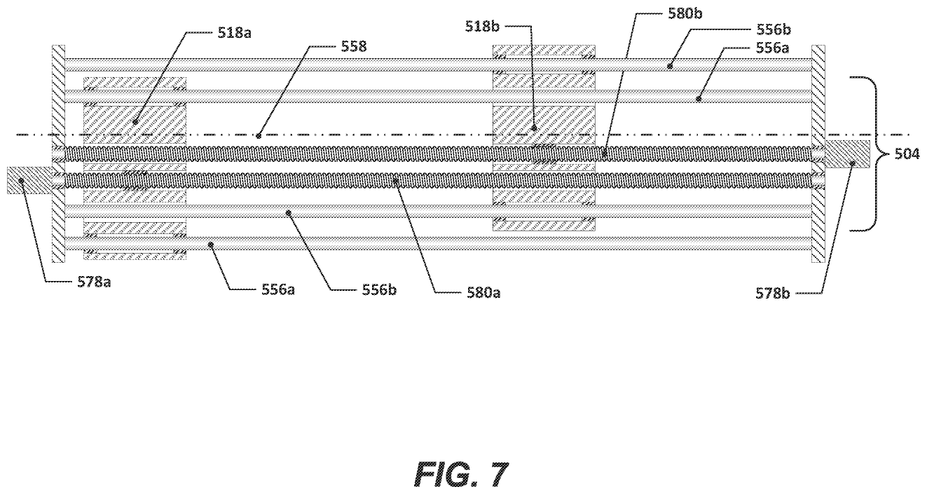

FIG. 7 shows an example linear translation system with two sets of linear guides 556, a first set of linear guides 556a and a second set of linear guides 556b. The first base 518a is attached the first set of linear guides 556a and the second base 518b is attached to the second set of linear guides 556b. Both sets of linear guides are substantially parallel to the translation axis 558. Each base 518 may be driven by a corresponding linear drive system. The first base 518a may be driven along the first set of linear guides 556a by the first linear drive motor 578a and the first linear drive screw 580a. The second base 518b may be driven along the second set of linear guides 556b by the second linear drive motor 578b and the second linear drive screw 580b. Similar to the single linear guide system in FIG. 6, the two sets of linear guides may allow each base 518 to be driven along the translation axis 558 independent of the other.

The linear translation system 504 is configured so that the first wafer handling robot arm via the first base 518a is able to translate independently from the second wafer handling robot arm via a second base 518b. Each linear drive system may be independently controlled so that each base 518 may move independently from the other (although the travel of one base may be limited based on the positioning of the other base, as both are able to translate through at least some common regions). For example, the first base 518a is able to travel a first direction along the translation axis 558 while the second base 518b remains stationary. In this example, the first linear drive motor 578a may drive the first linear drive screw 580a causing the first base 518a to move in the first direction. Concurrently, the second linear drive motor 578b may be idle, thus the second base 518b may remain stationary. In another example, the first base 518a and the second base 518b may translate along the same direction but at different speeds. In this example, the first linear drive motor 578a may drive the first linear drive screw 580a at a first rate causing the first base 518a to move in the first direction at a first speed. The second linear drive motor 578b may drive the second linear drive screw 580b at a second rate causing the second base 518a to move in the first direction at a second speed. Thus, both the first base 518a and second base 518b may move in the first direction but at different speeds. Since each base 518 can be controlled independently of the other base, each of the wafer handling robot arms, mounted to their corresponding base, can be controlled to translate along the translation axis 558 independently of the other. The above examples are provided illustrate aspects of various embodiments. These examples are provided to exemplify and more clearly illustrate aspects and are not intended to be limiting.

Moving back to FIG. 4, the linear translation system 404 has three translation zones along the translation axis 458, a first zone 460, a second zone 462, and a third zone 464 according to some embodiments. The second zone 462 is between the first zone 460 and the third zone 464. Either wafer handling robot arm 406 or 408 is able to translate along the translation axis to any location within the second zone 462 as long as the other wafer handling robot arm of the wafer handling robot arms 406 or 408 is not blocking the way. For example, the first wafer handling robot arm 406 can translate along the translation axis 458 so that the base 418 of the first wafer handling robot arm is in either the first zone 460 or the second zone 462. The base 418 of the first wafer handling robot arm 406 is unable to translate into the third zone because the base 418 of the second wafer handling robot arm 408 will block the base 418 of the first wafer handling robot arm 406 since the base 418 of the second wafer handling robot arm 408 cannot move any further. Similarly, the second wafer handling robot arm 408 can translate along the translation axis 458 so that the base 418 of the second wafer handling robot arm can translate throughout the second zone 462 and the third zone 464. Similar to the first wafer handling robot arm 406 and the third zone 464, the base 418 of the second wafer handling robot arm 408 cannot enter the first zone 460) since the base 418 of the first wafer handling robot arm 406 cannot move any further and blocks the base 418 of the second wafer handling robot arm from moving into the first zone 460.

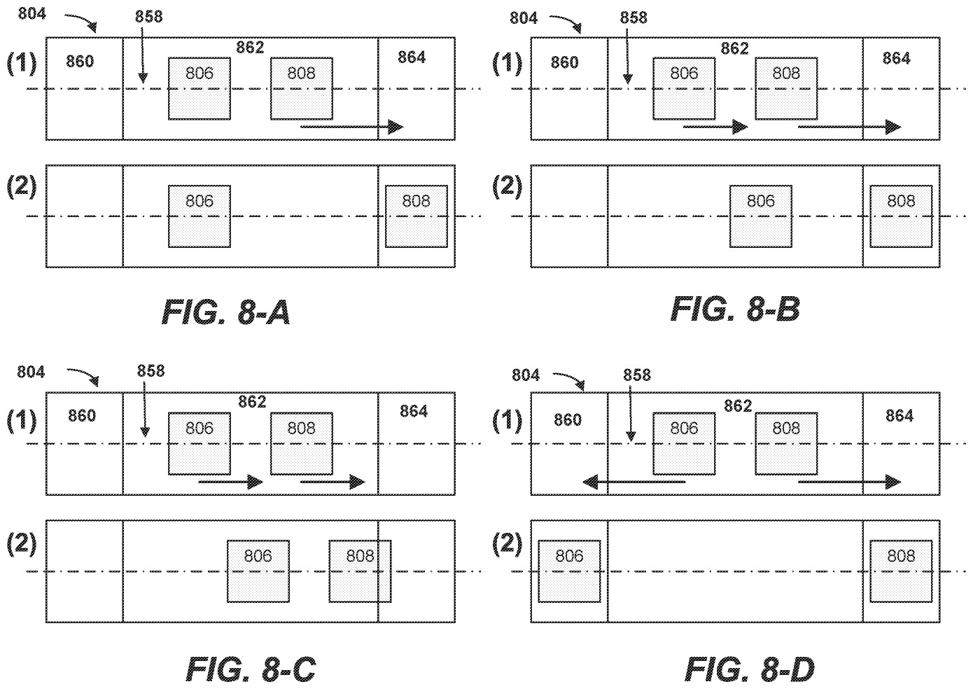

FIG. 8-A, FIG. 8-B, FIG. 8-C, and FIG. 8-D are four examples showing the two wafer handling robot arms translating independently of the other. The following examples are provided to further illustrate aspects of various embodiments. These examples are provided to exemplify and more clearly illustrate certain aspects and are not intended to be limiting. Shown in each of the figures is top view of a linear translation system 804, a representation of the base of the first wafer handling robot arm 806, and a representation of the base of the second wafer handling robot arm 808. In the linear translation system 804 are three translation zones, a first zone 860, a second zone 862, and a third zone 864, and a translation axis 858 which represents the direction the wafer handling robot arms are able to translate along. In each figure are two diagrams, diagram (1) which represents the initial position of each of the wafer handling robot arms and diagram (2) which represents the position of each of the wafer handling robot arms after a translation.

FIG. 8-A shows one wafer handling robot arm translating to a new position along the translation axis 858 while the other wafer handling robot arm remains stationary relative to the translation axis. As shown, the position of the base of the first wafer handling robot arm 806 remains in the same position in the second zone 862 in both diagram (1) and diagram (2), thus the first wafer handling robot arm has not translated. The base of the second wafer handling robot arm 808 has translated from a position in the second zone 862 in diagram (1) to a new position in the third zone 864 in diagram (2). The translation of the second wafer handling robot arm between the two diagrams is represented by the arrow. As shown in this example, the second wafer handling robot arm is able to translate along the translation axis 858 while the first wafer handling robot arm remains stationary.

FIG. 8-B shows both wafer handling robot arms concurrently translating along the translation axis 858. Both the base of the first wafer handling robot arm 806 and the base of the second wafer handling robot arm 808 translate right along the translation axis 858 from their respective initial position in diagram (1) to their final position in diagram (2). While both wafer handling robot arms translate to the right along the translation axis 858, the base of the second wafer handling robot arm 808 moves a greater distance along the translation axis 858 than the base of the first wafer handling robot arm 806. Since the translation by the base of the second wafer handling robot arm 808 is greater than the translation of the base of the first wafer handling robot arm 806, the distance between the base of the first wafer handling robot arm and the base of the second wafer handling robot arm 808 in diagram (2) is greater than the distance between the two wafer handling robot arms in diagram (1).

FIG. 8-C shows both wafer handling robot arms translating from their respective initial position in diagram (1) to the right along the translation axis 858 to their final position in diagram (2). Both wafer handling robot arms translate the same distance to the right along the translation axis 858. The distance between the base of the first wafer handling robot arm 806 and the base of the second wafer handling robot arm 808 in the initial position in diagram (1) is the same as the distance between the two wafer handling robot arms after the translation shown in diagram (2). During the actual translation, the two wafer handling robot arms may translate at the same time at the same speed, maintaining the same distance between the two wafer handling robot arms throughout the translation or may, alternatively, travel at different speeds and be separated by a varying distance.

FIG. 8-D show both wafer handling robot arms translating along the translation axis 858 in different directions. The base of the first wafer handling robot arm 806 translates to the left along the translation axis 858 while the base of the second wafer handling robot arm 808 translates to the right along the translation axis. As shown, both wafer handling robot arms started in the second zone 862. The base of the first wafer handling robot arm 806 translated to the left into the first zone 860, while the base of the second wafer handling robot arm 808 translated to the right into the third zone 864. As shown in the four examples, the wafer handling robot arms are able to translate concurrently and independently in two different directions, with different speed, or by different amounts in the same direction, along the translation axis 858. By having each of the wafer handling robot arms translate along the translation axis 858 independently, the two wafer handling robot arms may work independently of one another which improves tool efficiency and increased wafer throughput. For example, the two wafer handling robot arms may each pick processed wafers from a load lock and place each wafer in a respective, potentially spaced-apart FOUP (such as FOUPs at opposite ends of a series of FOUPs). They may similarly each concurrently pick a to-be-processed wafer from respective FOUPs (which may similarly be spaced apart) and both move towards the load lock in the second zone 862 and place the wafers in the load lock. This may occur concurrently so that the time taken to load and unload wafers in and from a multiple wafer load lock may be reduced.

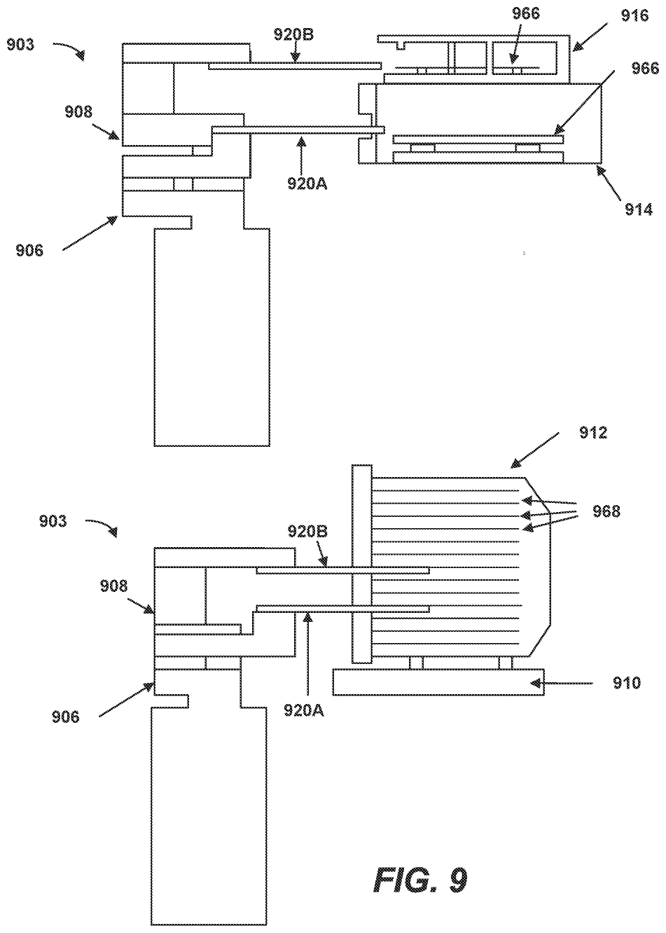

Moving back to FIG. 4, the nesting wafer handling robot arms 403 are in a nested configuration. In the nested configuration, the end effector 420A of the first wafer handling robot arm 406 and the end effector 420B of the second wafer handling robot arm 408 are positioned above one another. This allows both of the wafer handling robot arms to pick from or place onto two locations where one location is above the other. For example, as shown in FIG. 1, the wafer handling robot arms may be able to pick from two different slots in a single FOUP 112. In another example, one of the wafer handling robot arms places a wafer on the aligner 116 and the other wafer handling robot arm concurrently places a second wafer in the load lock 114. A side view of the two examples are shown in FIG. 9-A and FIG. 9-B.

FIG. 9-A shows a side view of the nesting wafer handling robot arms 903 in a nested configuration, that is the end effector 920 of one wafer handling robot arm is directly above the end effector of the other wafer handling robot arms. In this example, an end effector 920B of a second wafer handling robot arm 908 is above an end effector 920A of a first wafer handling robot arm 906. The two robot arms are in position to concurrently place a wafer in two different locations, one location directly above the other. In this example, the top location is an aligner 916 directly above the bottom location a load lock 914. As discussed above, the load lock is used to transfer wafers from an environment with atmospheric pressure to a processing chamber or a vacuum transfer chamber (not shown), which, generally speaking, has an environment with pressure below atmospheric pressure. The aligner 916 is used to rotate wafers prior to entering the load lock 914 to ensure the wafer is properly orientated for wafer processing. The two wafer handling robot arms are able to position the end effectors directly above one another. A corresponding vertical drive mechanism (not shown) of each wafer handling robot arm may move the corresponding end effector along a z-drive axis so that the end effectors are spaced apart by the same distance between a wafer support surface 966 in the aligner 916 and a wafer support surface 966 in the load lock 914. The two wafer handling robot arms, while in the nested position, can pick wafers concurrently, can place wafers concurrently, or have one wafer handling pick a wafer while the other wafer handling robot arm place a wafer concurrently. For example, the second wafer handling robot arm 908 can place a wafer in the aligner 916 while the first wafer handling robot arm 906 picks a wafer in the load lock 914. This allows the wafer in the aligner to be aligned while the wafer in the load lock is removed.

FIG. 9-B shows the nesting wafer handling robot arms 903 in a nested configuration about to pick from a FOUP 912. The FOUP 912 rests on a load port 910 of the EFEM (not shown). As discussed above in FIG. 1, there may be multiple FOUPs docked within a single EFEM. The FOUP 912 has multiple slots 968 used to store semiconductor wafers. Generally speaking, the slots 968 in the FOUP 912 are spaced 10 mm apart. The nesting wafer handling robot arms 903 are able to position their respective end effectors 920 so that that distance between the two end effectors matches the position of the corresponding slot 968 that each wafer handling robot arm will pick from. For example, if the wafer handling robot arms will pick from consecutive slots 968 in the FOUP 912, the end effector 920 of one wafer handling robot arm will be 10 mm directly above the end effector of the other wafer handling robot arm. The nesting wafer handling robot arms 903 can concurrently pick corresponding wafers from corresponding slots 968 in the same FOUP 912. In another example, the nesting wafer handling robot arms 903 can concurrently place corresponding wafers into corresponding slots 968 in the same FOUP 912. In still another example, the nesting wafer handling robot arms 903 can have one wafer handling robot arm concurrently pick a wafer from a corresponding slot 968 in the FOUP while the other wafer handling robot arm concurrently places a wafer into a corresponding slot in the same FOUP.

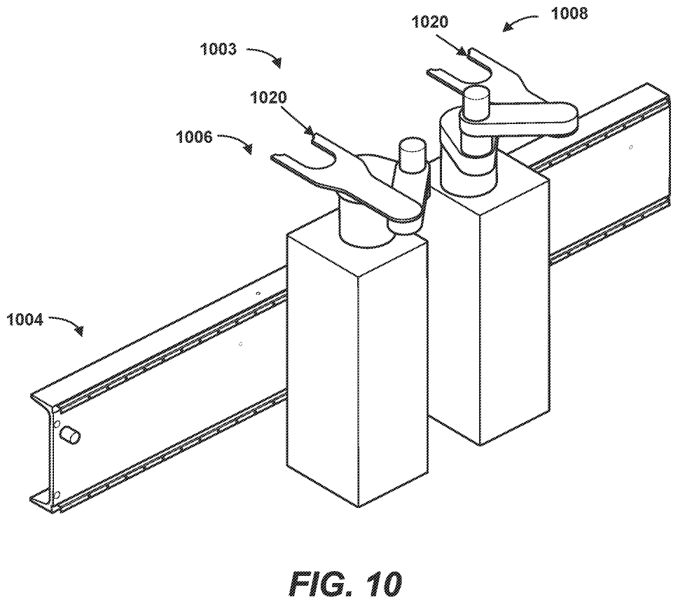

The nesting wafer handling robot arms are able to pick and place wafers concurrently to the other in locations spaced a horizontal distance apart. Shown in FIG. 10 is an isometric view of the nesting wafer handling robot arms 1003 preparing to pick wafers from locations a horizontal distance apart. In the example shown, a first wafer handling robot arm 1006 and a second wafer handling robot arm 1008 prepare to pick wafers at wafer placement locations on the same side as a linear translation system 1004. In previous examples, the nesting wafer handling robot arms 1003 picked and placed wafers in locations above one another. In this example, the end effector 1020 of both the first wafer handling robot arm 1006 and the second wafer handling robot arm 1008 are in positions spaced a horizontal distance apart from the other. Each wafer handling robot arm may have a vertical drive mechanism that can be used to place the corresponding end effector at the height of the other end effector on the other wafer handling robot arm. The vertical drive mechanism allows each wafer handling robot arm to concurrently pick and place at locations level with a second location where the other wafer handling robot arm is picking and/or placing wafers (or at different levels, such as at different FOUP wafer heights). In some instances, the two locations where the two wafer handling robot arms are picking and/or placing wafers may have a horizontal distance between the two locations and are at different elevations from one another.

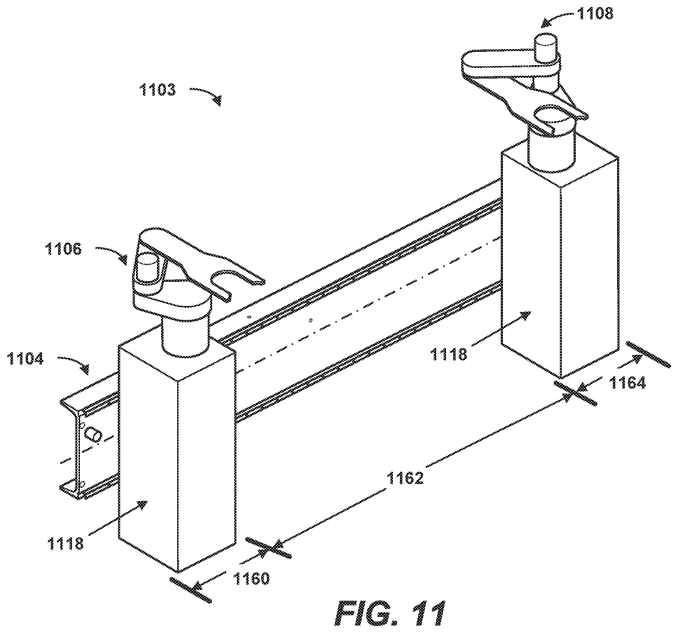

Shown in FIG. 11 is another isometric view of nesting wafer handling robot arms 1103 spaced a horizontal distance apart. A first wafer handling robot arm 1106 and a second wafer handling robot arm 1108 prepare to pick wafers from wafer locations on far ends of a linear translation system 1104. The two wafer handling robot arms are at the furthest ends of the linear translation system 1104, the first wafer handling robot arm 1106 is in a first zone 1160 of the linear translation system and the second wafer handling robot arm 1108 is in a third zone 1164 of the linear translation system. As discussed earlier, the two wafer handling robot arms are able to pick and place wafers independent of one another at locations spaced a horizontal distance apart from one another. In this example, the two wafer handling robot arms are picking wafers while the corresponding bases 1118 of the wafer handling robot arms are in separate zones of the linear translation system 1104.

In the examples shown in FIG. 11 the two nesting wafer handling robot arms 1103 are shown on a first side of the linear translation system 1104. In some embodiments (not shown), a first wafer handling robot arm may be mounted on a first side of a linear translation system and a second wafer handling robot arm may be mounted on a second side of the linear translation system. Each wafer handling robot arm may be configured to travel along the entire length of the translation system.

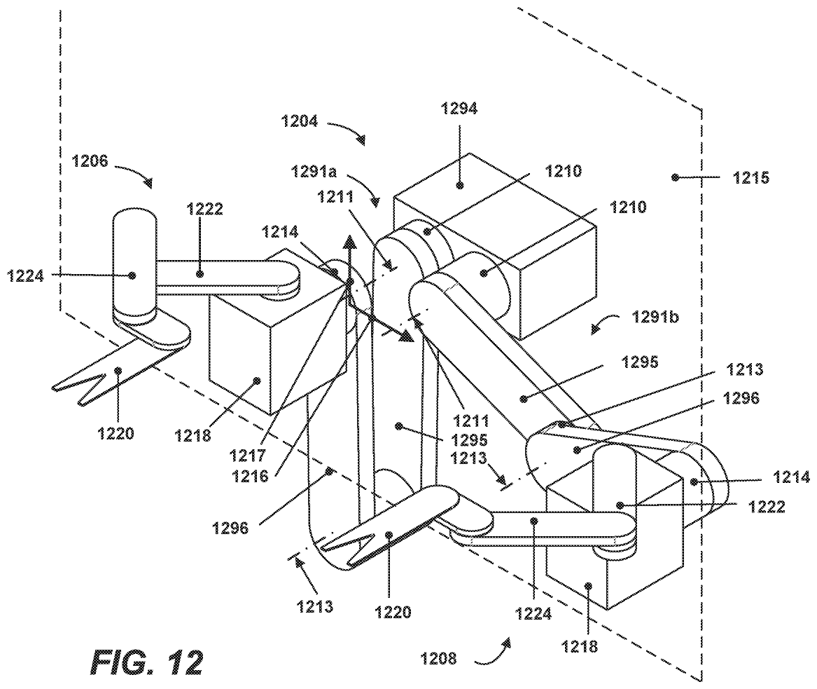

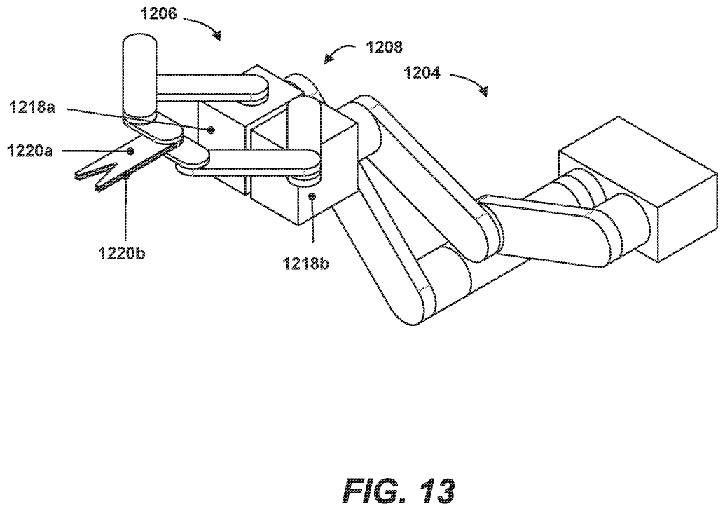

The linear translation systems discussed above are one example of a linear translation system that may be used to provide the nesting robot arm systems discussed herein; a further linear translation system is described below with respect to FIGS. 12 and 13.

FIG. 12 is an isometric view of another example of nesting wafer handling robot arms with a linkage-based translation system 1204. In the example shown, the wafer handling robot arms include two wafer handling robot arms, a first wafer handling robot arm 1206 and a second wafer handling robot arm 1208. Each wafer handling robot arm has a corresponding base 1218, robot arm links, and an end effector 1220. Each wafer handling robot arm in this example has two arm links, a first arm link 1222 and a second arm link 1224, although other similar configurations may feature wafer handling robot arms with a different number of arm links, e.g., three or four arm links.

In the linkage-based translation system 1204 shown, the linkage-based translation system 1204 has a linkage-based translation system base 1294. The linkage-based translation system base 1294 has two translation link sets 1291a and 1291b. Each translation link set 1291 is connected to, and supports, a corresponding one of the wafer handling robot arms. The first translation link set 1291a is connected to the base 1218 of the first wafer handling robot arm 1206 and the second translation link set 1291b is connected to the base 1218 of the second wafer handling robot arm 1208. In some embodiments, each translation link set 1291 may have two or more links. In the embodiment shown, each translation link set 1291 has two links, a first link 1295 and a second link 1296. In some embodiments, the first link 1295 and the second link 1296 may be the same size. In some embodiments, each link may be a different size, e.g., the first link 1295 may be longer than the second link 1296. In the embodiment shown, the first link 1295 and the second link 1296 of each translation link set 1291 are the same size.

Each first end of the first links 1295 rotatably connects to the linkage-based translation system base 1294 by way of a corresponding first rotational joint 1210 and is rotatable about a first rotational axis 1211. In some implementations, each first link 1295 may be configured to rotate 360° about the first rotational axis 1211 and may rotate in both the clockwise and counter-clockwise direction. In such implementations, each first link 1295 may rotate such that a second end of the first link may be moved into or through a position directly below the linkage-based translation system base 1294. Similarly, each first link 1295 may also, in such implementations, rotate such that the second end of the first link may be moved into or through a position directly above the linkage-based translation system base 1294. In some embodiments, depending on the length of the arm links, a cavity may be built into a floor beneath the linkage-based translation system base 1294. The cavity may allow each of the arm links to rotate downward such that the elbow joints thereof (between the first links 1295 and the second links 1296) swing down into the cavity and avoid hitting the floor, thus allowing the bases 1218 to be located closer to the floor than they would otherwise be. Each first end of the second links 1296 rotatably connects to corresponding second end of the first links 1295 by way of a corresponding second rotational joint 1212 and is rotatable about a corresponding second rotational axis 1213. Each second rotational axis 1213 is substantially parallel to the first rotational axes 1211. The base 1218 of each wafer handling robot arm rotatably connects to a corresponding second end of the second link 1296 of a corresponding translation link set 1291 by way of a third rotatable joint 1214.

The linkage-based translation system 1204 shown can move the first wafer handling robot arm 1206 and the second wafer handling robot arm 1208 independently of one another. In some implementations, the linkage-based translation system 1204 may feature translation link sets 1291 that may be driven by a plurality of motors located in the linkage-based translation system base 1294 such that the linkage-based translation systems 1204 each have more than a single degree of freedom so as to be able to move the wafer handling robot arms in any direction along a translation plane 1215. The translation plane 1215 is perpendicular to the first rotational axes 1211. For example, each of the linkage-based translation systems 1204 may be configured to be able to move the wafer handling robot arm supported thereby along a horizontal axis 1216, a vertical axis 1217, or in a direction or along a path that has components along both the horizontal axis 1216 and the vertical axis 1217. In such implementations, vertical movement of the end effectors of the wafer handling robot arms 1206 and 1208 may, instead of being facilitated through actuators located in the bases 1218 thereof, be facilitated through actuation of the translation link sets 1291.

In other implementations of a linkage-based translation system, the translation link sets may be more limited in their motion range, e.g., each having only a single degree of freedom. In such implementations, a single drive motor may drive each translation link set, causing the first links 1295 thereof to rotate relative to the linkage-based translation system base 1294. The remaining link of each translation link set and the corresponding base 1218 supported thereby may be kinematically linked to the movement of the first link of that translation link set 1291 such that such rotation causes the base 1218 supported thereby to translate along the horizontal axis 1216 without rotation or vertical translation (slight displacement due to gravitational loading and flexure of the translation links is not, for the purposes of this disclosure, considered to be translational movement).

The linkage translation system 1204 may move the wafer handling robot arms so that the bases 1218 thereof are spaced a horizontal distance apart. Shown in FIG. 12, the two wafer handling robot arm bases 1218 are level with each other. The first wafer handling robot arm 1206 is positioned directly in front of the base 1294 of the linkage translation system 1204 while the second wafer handling robot arm 1208 is positioned to the right of the linkage-based translation system base 1294. Similar to the linear translation systems discussed above, the linkage translation system 1204 may move the bases 1218 of the wafer handling robot arms independently of each other.

FIG. 13 shows the wafer handling robot arms with the linkage-based translation system 1204 in a nested configuration. In the nested wafer configuration, an end effector 1220a of the first wafer handling robot arm 1206 is directly above an end effector 1220b of the second wafer handling robot arm 1208. The linkage-based translation system 1204 is able to move the bases 1218 of the wafer handling robot arms next to each other, allowing each wafer handling robot arm to position its corresponding end effector in a position vertically in-line with the end effector of the other wafer handling robot arm. It will be understood that such a side-by-side arrangement of the bases 1218 may also be obtained using other positions of the translation link sets 1291. Thus, the linkage-based translation system 1204 may be used to produce translational movements of the wafer handling robot arms 1206 and 1208 that are similar to those that may be obtained using the linear translation systems discussed earlier herein, and it will be recognized that the movements described above with respect to the earlier-discussed linear translation system implementations may also be replicated using a linkage-based translation system as shown in FIGS. 12 and 13.

The linkage-based translation system may be used in a semiconductor wafer processing tool. For example, the linkage-based translation system may be used in an EFEM. In another example, the linkage-based translation system may be used in a vacuum transfer module. When the linkage-based translation system is used in an EFEM, the base of the linkage-based translation system may be on either side of the EFEM. Generally speaking, the EFEM may have one or more FOUPs on a first side and one or more load locks on a second side opposite of the first side (see FIG. 1). In some embodiments, the linkage-based translation system may be mounted on the first side, the same side as the one or more FOUPs. In some embodiments the linkage-based translation system may be mounted on the second side, the same side as the one or more load locks.

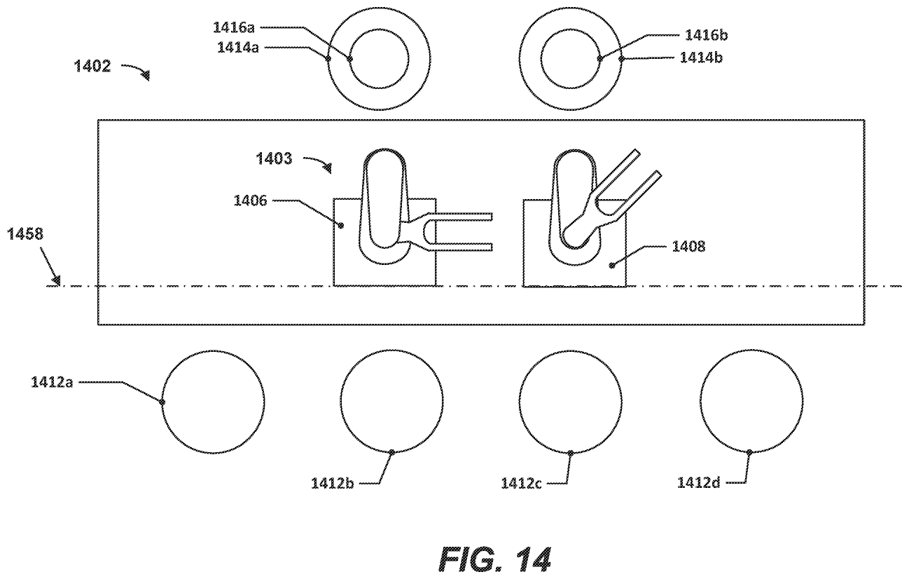

FIG. 14 is a schematic view of an embodiment of an EFEM 1402. In the EFEM 1402 are nesting wafer handling robot arms 1403, a first wafer handling robot arm 1406 and a second wafer handling robot arm 1408. Shown are four FOUPs 1412, a first FOUP 1412a, a second FOUP 1412b, a third FOUP 1412c, and a fourth FOUP 1412d. In the embodiment shown, there are two load locks 1414, a first load lock 1414a and a second load lock 1414b and two aligners 1416, a first aligner 1416a and a second aligner 1416b, each placed above a corresponding load lock. The nesting wafer handling robot arms 1403 include a first wafer handling robot arm 1406 and a second wafer handling robot arm 1408 with bases configured to translate along a translation axis 1458 of a linear translation system (not shown). Each of the wafer handling robot arms may perform operations independent of the operations being performed by the other wafer handling robot arm. For example, depending on the positioning of each of the wafer handling robot arms, each wafer handling robot arm can perform operations such as pick wafers, place wafers, translate along the translation axis, etc. While either wafer handling robot arms can perform operations independent of the other, the two wafer handling robot arms may perform operations in coordination to increase wafer throughput on the tool. Listed below are examples of how the nesting wafer handling robot arms 1403 cooperate together. The following examples are provided to further illustrate aspects of various embodiments. These examples are provided to exemplify and more clearly illustrate aspects and are not intended to be limiting.

In the first example, the first wafer handling robot arm 1406 and the second wafer handling robot arm 1408 perform operations to transfer a first wafer and a second wafer from the first FOUP 1412a to the load locks 1414. The first wafer handling robot arm 1406 and the second wafer handling robot arm 1408 translate along the translation axis 1458 to a position where both wafer handling robot arms can pick from the first FOUP 1412a, e.g., next to each other with the first rotational joints of both wafer handling robot arms generally an equal distance from a center axis that is perpendicular to the translation axis and that passes through the centers of the first and second wafers. Once the base of each wafer handling robot arm is in position, the two wafer handling robot arms may be caused to move into a nested configuration where end effectors of each wafer handling robot arm are placed in a position where one is above the other in front of the first FOUP 1412a, e.g., with corresponding top surfaces spaced apart vertically by 10 mm. The two wafer handling robot arms may then concurrently pick the corresponding wafers from the first FOUP 1412a. In some embodiments, the pick action can be substantially simultaneous, and in other embodiments, the pick action may be sequential among the end effectors. After each wafer handling robot arms picks a corresponding wafer, the wafer handling robot arms may translate along the translation axis 1458 so that the first wafer handling robot arm 1406 is near a first aligner 1416a and a first load lock 1414a and the second wafer handling robot arm 1408 is near a second aligner 1416b and a second load lock 1414b as shown in FIG. 14. The first wafer handling robot arm 1406 may place the first wafer into the first aligner 1416a while the second wafer handling robot arm 1408 concurrently places the second wafer into the second aligner 1416b. The two aligners 1416 rotate and align their corresponding wafers. Once the wafers are aligned the two wafer handling robot arms may concurrently pick the corresponding wafers from the corresponding aligners 1416. The first wafer handling robot arm 1406 may place the first wafer into the first load lock 1414a and the second wafer handling robot arm 1408 may concurrently place the second wafer into the second load lock 1414b. The operations to move both the first wafer and second wafer may occur in parallel with each other, i.e., at least partially simultaneously.

In some embodiments of the EFEM 1402, there are no aligners and the wafers may be placed directly into the load locks 1414 from the FOUP 1412. In this embodiment, once the wafer handling robot arms pick the corresponding wafers from the appropriate FOUP 1412, each wafer handling robot arm places its corresponding wafer into the corresponding load lock 1414. For example, the first wafer handling robot arm 1406 with the first wafer from the first FOUP 1412a may place the first wafer into the first load lock 1416a directly from the first FOUP 1412a and the second wafer handling robot arm 1408 with the second wafer from the first FOUP 1412a will concurrently place the second wafer into the second load lock 1416b directly from the first FOUP 1412a.

The two wafer handling robot arms may also be caused to complete a similar process as described above but may instead pick from two different FOUPS 1412 instead of a single FOUP. In this example, the first wafer handling robot arm 1406 picks a first wafer from the second FOUP 1412b and the second wafer handling robot arm 1408 concurrently picks a second wafer from the fourth FOUP 1412d (it will be understood that other implementations, different FOUPs may be selected/picked from). The two wafer handling robot arms will continue with the process as described above so that both wafers are concurrently placed into the aligners 1416 and/or the load locks 1414 after each wafer is concurrently picked from their corresponding FOUP 1412.

In another example, the two wafer handling robot arms may work to ensure that the load locks are in constant or near-constant use and experience minimal delay from wafer loading or unloading operations. In this example, a first wafer may be done processing and ready to be moved back into the atmospheric pressure conditions in the EFEM 1402 from the first load lock 1414a. The first wafer handling robot arm 1406 may pick a second wafer from the second FOUP 1412b and place the second wafer in the first aligner 1416a. The second wafer handling robot arm 1408 may concurrently pick the first wafer from the load lock 1414a and place the wafer in the fourth FOUP 1412d. The second wafer handling robot arm may then pick a third wafer from the third FOUP 1412c. Once the second wafer is aligned, the first wafer handling robot arm may pick the first wafer from the aligner 1416a. The first wafer handling robot arm may then place the first wafer from the aligner 1416a into the first load lock 1414a while the second wafer handling robot arm concurrently places the third wafer from the FOUP 1412c into the first aligner 1416a. To do this, the two wafer handling robot arms may move back into the nested configuration. By handling wafers through this method, as soon as a wafer handling robot arm picks a wafer from the load lock 1414a, the other wafer handling robot arm is ready to place a new wafer into the load lock. This ensures that load locks are more efficiently used and have a reduced wait for wafers to be loaded.

By having an EFEM 1402 with two wafer handling robot arms, a tool may be able to improve its throughput. When compared to a tool with a single wafer handling robot arm in the EFEM, the two wafer handling robot arms may pick two wafers from a FOUP and place two wafers concurrently into a load lock. This may double throughput. For example, consider a system with a single EFEM wafer handling robot arm that has an average cycle time of 13.4 seconds for the wafer handling robot arm to pick a wafer from a FOUP, travel to a load lock, place the wafer in a load lock, pick a processed wafer from the load lock, travel to the FOUP, and place the wafer in the FOUP. If the load lock needs two wafers and only has one wafer handling robot arm, two such cycles would need to be sequentially performed for a total of 26.8 seconds for the wafer handling robot arm to load two wafers into the load lock. However, if the same example system is instead equipped with two wafer handling robot arms, each wafer handling root may concurrently pick a corresponding wafer from a FOUP, travel to a load lock, place the wafer in a load lock, pick a processed wafer from the load lock, travel to the FOUP, and place a processed wafer in the FOUP, and thus two wafers may be loaded into the load lock in the cycle time of a loading a single wafer. Thus, while the wafer handling robot arms work at the same rate, they are able to get twice as much done than with one wafer handling robot arm. In the first example, assuming the throughput is the bottle neck, the single wafer handling robot arm may load approximately 269 wafers in an hour. In the second example, assuming the throughput is the bottle neck of the tool, the dual wafer handling robot arm may load approximately 537 wafers in an hour.

As discussed above, in some implementations, a controller may be part of the nesting wafer handling robot arms discussed herein. FIG. 1 depicts a schematic of an example controller 170 with one or more processors 172 and a memory 174, which may be integrated with electronics for controlling the operation of the first wafer handling robot arm 106, the second wafer handling robot arm 108, the linear translation system 104, the load locks 114, and the aligner 116. The controller, depending on the processing requirements and/or the type of system, may be programmed to control any of the processes disclosed herein, such as processes for controlling the linear translation system 104 and the nesting wafer handling robot arms 103, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

It will be understood that the wafer handling robot arms discussed and depicted herein may be configured so as to have equal-length arm links, e.g., equal-length first and second arm links, or unequal-length arm links, e.g., unequal-length first and second arm links. Thus, even if two arm links of a wafer handling robot arm are shown in a particular figure as being of equal length (with length referring to the distance between rotational axes associated with opposing ends of the link), it is to be understood that those depicted links may also be designed so as to be of unequal length as well. Similarly, if two arm links of a wafer handling robot are shown in a particular figure as being of unequal length, it is to also be understood that those depicted links may also be designed so as to be of equal length as well.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example nesting wafer handling robot arms and linear translation systems according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It is to be understood that the phrases “for each <item>of the one or more <items>,” “each <item>of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. An apparatus for transferring wafers in a semiconductor processing tool, the apparatus comprising:
a first wafer handling robot arm;
a second wafer handling robot arm; and
a linear translation system configured to interface with the first and the second wafer handling robot arms, wherein:
the first wafer handling robot arm and the second wafer handling robot arm each have a corresponding base and a corresponding first end effector;
the apparatus is configured to cause the bases to independently traverse along a horizontal translation axis between at least a nested configuration and a non-nested configuration;
the linear translation system, the first wafer handling robot arm, and the second wafer handling robot arm are configured such that:
the base of the first wafer handling robot arm is movable by the linear translation system, along the translation axis, and through a first zone and a second zone but not a third zone, and such that the base of the second wafer handling robot arm is moveable by the linear translation system, through the second zone and the third zone but not the first zone,
the second zone is between the first zone and the third zone,
the first end effector of the first wafer handling robot arm connects with a link of the first wafer handling robot arm from above, and
the first end effector of the second wafer handling robot arm connects with a link of the second wafer handling robot arm from below.

2. The apparatus of claim 1, wherein the first wafer handling robot arm and the second wafer handling robot arm each further include two or more corresponding robot arm links including at least (a) a corresponding first robot arm link with a corresponding first end and a corresponding second end, with the first end of the corresponding first robot arm link rotatably connected to the corresponding base via a corresponding first rotational joint such that the corresponding first robot arm link is rotatable relative to the corresponding base about a corresponding first axis, and (b) a corresponding second robot arm link with a first end and a second end, with the second end of the corresponding second robot arm link rotatably connected with the corresponding first end effector via a corresponding second rotational joint such that the corresponding first end effector is rotatable relative to the corresponding second robot arm link about a corresponding second axis.

3. The apparatus of claim 2, wherein the corresponding bases of the first wafer handling robot arm and the second wafer handling robot arm each have a corresponding vertical drive mechanism configured to cause the corresponding first end effector to move along an axis parallel to the corresponding first axis.

4. The apparatus of claim 1, wherein the linear translation system includes a first set of linear guides and both the first wafer handling robot arm and the second wafer handling robot arm are movably connected with the first set of linear guides.

5. The apparatus of claim 1, wherein the linear translation system has a first set of linear guides and a second set of linear guides, the first wafer handling robot arm is movably connected with the first set of linear guides, and the second wafer handling robot arm is movably connected with the second set of linear guides.

6-8. (canceled)

9. The apparatus of claim 2, wherein each wafer handling robot arm has a corresponding second end effector.

10. The apparatus of claim 2, further comprising a controller having one or more memory devices communicatively connected with one or more processors.

11. The apparatus of claim 10, wherein the controller is configured to cause the first and second wafer handling robot arms to move between at least a first configuration and a second configuration, wherein:
in the first configuration, the first and second wafer handling robot arms are positioned such that the first end effector of the second wafer handling robot arm is directly above the first end effector of the first wafer handling robot arm and the first axis of the second wafer handling robot arm is spaced a first distance apart from the first axis of the first wafer handling robot arm,
in the second configuration, the first and second wafer handling robot arms are positioned such that the first end effector of the second wafer handling robot arm is a horizontal distance apart from the first end effector of the first wafer handling robot arm and the first axis of the second wafer handling robot arm is spaced a second distance apart from the first axis of the first wafer handling robot arm, and
the second distance is greater than the first distance.

12-17. (canceled)

18. The apparatus of claim 10, wherein the controller is configured to cause the first wafer handling robot arm to pick a first substrate from a first wafer placement location and to cause the second wafer handling robot arm to concurrently pick a second substrate from a second wafer placement location, the first wafer placement location positioned above or below the second wafer placement location.

19. The apparatus of claim 10, wherein the controller is configured to cause the first wafer handling robot arm to pick a first substrate from a first wafer placement location and to cause the second wafer handling robot arm to concurrently pick a second substrate from a second wafer placement location, the second wafer placement location spaced a horizontal distance apart from the first wafer placement location.

20. The apparatus of claim 19, wherein the controller is further configured to cause the first wafer handling robot arm to place the first substrate at a third wafer placement location and to cause the second wafer handling robot arm to concurrently place the second substrate at a fourth wafer placement location, the third wafer placement location positioned above or below the fourth wafer placement location.

21. The apparatus of claim 19, wherein the controller is further configured to cause the first wafer handling robot arm to place the first substrate at a third wafer placement location and to cause the second wafer handling robot arm to concurrently place the second substrate at a fourth wafer placement location, the third wafer placement location spaced a horizontal distance apart from the fourth wafer placement wafer location.

22. The apparatus of claim 1, further comprising three or more load ports and two or more load locks, wherein the three or more load ports are located on a first side of the linear translation system, the two or more load locks are on a second side of the linear translation system opposite the first side, and each of the three or more load ports are configured to receive a corresponding front opening universal pod.

23. The apparatus of claim 22, further comprising two or more aligners, with each aligner located above a corresponding load lock.

24. The apparatus of claim 22, wherein the controller is further configured to cause the first wafer handling robot arm to pick a first substrate from a first front opening universal pod and to cause the second wafer handling robot arm to concurrently pick a second substrate from the first front opening universal pod.

25. The apparatus of claim 22, wherein the controller is further configured to cause the first wafer handling robot arm to pick a first substrate from a first front opening universal pod and to cause the second wafer handling robot arm to concurrently pick a second substrate from a second front opening universal pod.

26-28. (canceled)

29. The apparatus of claim 1, wherein the linear translation system is a linkage-based translation system that has a first set of linkages connected with, and supporting, the base of the first wafer handling robot arm and a second set of linkages connected with, and supporting, the base of the second wafer handling robot arm.

30. The apparatus of claim 29, wherein the linkage-based translation system has a base and each set of linkages has at least (a) a corresponding first link with a corresponding first end and a corresponding second end, with the first end thereof rotatably connected to the base of the linkage-based translation system via a corresponding first rotational joint such that the corresponding first link is rotatable relative to the base of the linkage-based translation system about a corresponding a first axis, and (b) a corresponding second link with a first end and a second end, with the first end thereof rotatably connected with the second end of the corresponding first link and the second end thereof rotatably connected with the base of a corresponding one of the wafer handling robot arms via a corresponding rotational joint such that the corresponding wafer handling robot arm is rotatable relative to the corresponding second link about a corresponding second axis.

31. The apparatus of claim 30, wherein the linkage-based translation system is configured such that the second end of each second link is constrained to move along the translation axis.

32. The apparatus of claim 30, wherein the linkage-based translation system is configured such that the second end of each second link is constrained to move along a translation plane that is perpendicular to the first axes.
